(19) United States
(12) Patent Application Publication
(10) Pub. No.: US 2018/0124882 A1
(43) Pub. Date: May 3, 2018

(54) METHODS AND APPARATUS FOR IMPLEMENTING TUNABLE LIGHT EMITTING DEVICE WITH REMOTE WAVELENGTH CONVERSION

(71) Applicant: Intematix Corporation, Fremont, CA (US)

(72) Inventor: Charles Edwards, Pleasanton, CA (US)

(73) Assignee: Intematix Corporation, Fremont, CA (US)

(21) Appl. No.: 15/640,236

(22) Filed: Jun. 30, 2017

Related U.S. Application Data
(63) Continuation of application No. 13/273,199, filed on Oct. 13, 2011, now abandoned.

(51) Int. Cl. H05B 33/08; H01L 25/075; F21V 23/00; H01L 33/50; F21V 3/00

(52) U.S. Cl. CPC H05B 33/086; F21V 3/00; H01L 25/0753; F21S 4/28; F21K 9/232; F21Y 2115/10; F21Y 2105/10; F21Y 2105/14; F21K 9/64; F21K 9/238; F21V 23/003; H01L 33/507; H01L 2924/00; H01L 2924/0002; H05B 33/0803

(57) ABSTRACT

A tunable light emitting device includes a plurality of solid-state light sources, a dimmer switch configured to generate a range of output powers for the light emitting device, a control circuit configured to translate an output power generated by the dimmer switch into an on/off arrangement of the plurality of light sources, and a wavelength conversion component comprising two or more regions with different photo-luminescent materials located remotely to the plurality of solid-state light sources and operable to convert at least a portion of the light generated by the plurality of solid-state light sources to light of a different wavelength, wherein the emission product of the device comprises combined light generated by the plurality of light sources and the two or more regions of the wavelength conversion component.

### FIELD

This disclosure relates to solid-state light emitting devices that utilize remote wavelength conversion, and particularly to a tunable light-emitting device.

### BACKGROUND

Color temperature is a characteristic of visible light that has important applications in lighting. The color temperature of a light source is a measurement of the hue generated by that light source that corresponds to the temperature of an ideal black-body radiator that radiates light of comparable hue. Color temperature is conventionally stated in the unit of absolute temperature, the kelvin, having the unit symbol K. Color temperatures over 5,000 K are called cool colors (blueish white), while lower color temperatures (2,700-3,000 K) are called warm colors (yellowish white through red)

Traditional incandescent light bulbs are configured to generate light of varying brightness during dimming operation. A dimmer switch typically controls the power provided to the light bulb. The larger the power provided to the light bulb, the greater the temperature of the light bulb filament and the brighter the light generated. For an incandescent light bulb, light is generated by thermal radiation and so its color temperature is essentially the temperature of the filament. Typical incandescent light bulbs generate light of a warm yellowish white hue (e.g., 2,700-3,000K) at full power and at lower powers, can produce light of an even warmer orangeish white hue (e.g., 1500K) that is not available in non-incandescent light bulbs.

Recently, white light emitting LEDs (“white LEDs”) have become more popular and more commonly used, replacing conventional fluorescent, compact fluorescent and incandescent light sources. White LEDs generally include one or more photo-luminescent materials (e.g., one or more phosphor materials), which absorb a portion of the radiation emitted by the LED and re-emit light of a different color (wavelength). The phosphor material may be provided as a layer on, or incorporated within a wavelength conversion component that is located remotely from the LED die. Typically, the LED generates blue light and the phosphor(s) absorbs a percentage of the blue light and re-emits yellow light or a combination of green and red light, green and yellow light, green and orange or yellow and red light. The portion of the blue light generated by the LED that is not absorbed by the phosphor material combined with the light emitted by the phosphor provides light which appears to the eye as being nearly white in color. Such white light LEDs are characterized by their long operating life expectancy (>50,000 hours) and high luminous efficacy (70 lumens per watt and higher).

For white LEDs, light is generated by two processes: electroluminescence and photoluminescence rather than thermal radiation. Thus, the emitted radiation does not follow the form of a black-body spectrum. These sources are assigned what is known as a correlated color temperature (CCT). CCT is the color temperature of a black body radiator which to human color perception most closely matches the light from the lamp.

Whereas some incandescent light bulbs, as described above, are capable of generating light that ranges from a warm yellowish white to a warmer orangeish white, white LED light emitting devices do not exhibit these same characteristics. This is because the color temperature of an incandescent light bulb changes in response to the power provided to the bulb whereas the correlated color temperature (CCT) of a white LED light emitting device changes in response to variations in photo-luminescent material or the material from which the LED is fabricated. Because the photo-luminescent materials and LED materials are fixed, when the power applied to the white LED light emitting device is lowered, the intensity of the emission product changes, but the correlated color temperature remains the same.

Thus, a problem with such devices involves the dimming/correlated color temperature (CCT) characteristics of such devices. Moreover, while some incandescent lights may be capable of generating light with a range of color temperatures between warm yellowish white and even warmer orangeish white, it may be desirable to have an even larger range of color temperatures. For example, a restaurant may want to tune a light bulb to generate bright bluish white light for large parties to create an exciting atmosphere and softer yellowish white light for intimate gatherings to create a warm and romantic atmosphere.

### BRIEF DESCRIPTION OF THE DRAWINGS

In order that the present invention is better understood light emitting devices and wavelength conversion components in accordance with the invention will now be described, by way of example only, with reference to the accompanying drawings in which like reference numerals are used to denote like parts, and in which:

FIGS. 1A and 1B illustrates a schematic partial cutaway plan and sectional views of a known light emitting device that utilizes remote wavelength conversion;

FIG. 2A illustrates a cross-sectional view of a tunable light emitting device according to some embodiments;

FIG. 2B illustrates a top view of a wavelength conversion component of the tunable light emitting device in FIG. 2A according to some embodiments;

FIG. 2C illustrates a top view of an arrangement of a plurality of LEDs of the tunable light emitting device in FIG. 2A according to some embodiments;

FIG. 3A illustrates a cross-sectional view of a tunable light emitting device according to some embodiments;

FIG. 3B illustrates a top view of a wavelength conversion component of the tunable light emitting device in FIG. 3A according to some embodiments;

FIG. 3C illustrates a top view of an arrangement of a plurality of LEDs of the tunable light emitting device in FIG. 3A according to some embodiments;

FIG. 4 illustrates a sectional view of a tunable light emitting device 400 that utilizes remote wavelength conversion in accordance with some other embodiments;

FIG. 5 illustrates a CIE (Commission Internationale de l'Eclairage) 1931 chromaticity diagram illustrating color tuning for the device of FIGS. 2A, 2B, 2C, 3A, 3B, 3C, and 4.

FIG. 6 illustrates a flowchart a method for tuning a light-emitting device according to some embodiments.

FIG. 7 illustrates a cross-sectional of a wavelength conversion component in accordance with some embodiments.

FIGS. 8A, 8B, and 8C illustrate an example of an application of a wavelength conversion component in accordance with some embodiments.

FIGS. 9A, 9B, and 9C illustrate another example of an application of a wavelength conversion component in accordance with some embodiments.

FIG. 10 illustrates another example of an application of a wavelength conversion component in accordance with some embodiments.

FIGS. 11A and 11B illustrate another example of an application of a wavelength conversion component in accordance with some embodiments.

FIG. 12 illustrates a perspective of another application of a wavelength conversion component in accordance with some embodiments.

FIGS. 13A and 13B illustrate another example of an application of a wavelength conversion component in accordance with some embodiments.

### SUMMARY

Embodiments of the invention concern a tunable light emitting device with remote wavelength conversion. In some embodiments, the tunable light emitting device includes a plurality of solid-state light sources, a dimmer switch configured to generate a range of output powers for the light emitting device, a control circuit configured to translate an output power generated by the dimmer switch into an on/off arrangement of the plurality of light sources, and a wavelength conversion component comprising two or more regions with different photo-luminescent materials located remotely to the plurality of solid-state light sources and operable to convert at least a portion of the light generated by the plurality of solid-state light sources to light of a different wavelength, wherein the emission product of the device comprises combined light generated by the plurality of light sources and the two or more regions of the wavelength conversion component.

In some other embodiments, a method for tuning a light emitting device includes generating an output power by a dimmer switch of the light emitting device, converting the generated output power into an on/off arrangement of a plurality of light sources of the light emitting device by a control circuit, and establishing an emission product comprising combined light generated by the plurality of light sources and a wavelength conversion component, wherein the wavelength conversion component comprises two or more regions with different photo-luminescent materials located remotely to the plurality of solid-state light sources.

In some other embodiments, the tunable light emitting device includes a plurality of solid-state light sources, the plurality of solid-state light sources comprising a first set of solid-state light sources and a second set of solid-state light sources; a dimmer switch configured to generate a range of output powers for the light emitting device; a control circuit configured to translate an output power generated by the dimmer switch into an on/off arrangement of the plurality of light sources; a first wavelength conversion component comprising a first photo-luminescent material, wherein the first set of solid-state light sources corresponds to the first wavelength conversion component and the first wavelength conversion component encloses the first set of solid-state light sources; and a second wavelength conversion component comprising a second photo-luminescent material, wherein the second set of solid-state light sources corresponds to the second wavelength conversion component and the second wavelength conversion component encloses the second set of solid-state light sources; and wherein an emission product of the device comprises combined light generated by the plurality of light sources, the first wavelength conversion component, and the second wavelength conversion component.

Further details of aspects, objects, and advantages of the invention are described below in the detailed description, drawings, and claims. Both the foregoing general description and the following detailed description are exemplary and explanatory, and are not intended to be limiting as to the scope of the invention.

### DETAILED DESCRIPTION

Various embodiments are described hereinafter with reference to the figures. It should be noted that the figures are not necessarily drawn to scale. It should also be noted that the figures are only intended to facilitate the description of the embodiments, and are not intended as an exhaustive description of the invention or as a limitation on the scope of the invention. In addition, an illustrated embodiment need not have all the aspects or advantages shown. An aspect or an advantage described in conjunction with a particular embodiment is not necessarily limited to that embodiment and can be practiced in any other embodiments even if not so illustrated. Also, reference throughout this specification to “some embodiments” or “other embodiments” means that a particular feature, structure, material, or characteristic described in connection with the embodiments is included in at least one embodiment. Thus, the appearance of the phrase “in some embodiment” or “in other embodiments” in various places throughout this specification are not necessarily referring to the same embodiment of embodiments.

For the purposes of illustration only, the following description is made with reference to photo-luminescent material embodied specifically as phosphor materials. However, the invention is applicable to any type of photo-luminescent material, such as either phosphor materials or quantum dots. A quantum dot is a portion of matter (e.g. semiconductor) whose excitons are confined in all three spatial dimensions that may be excited by radiation energy to emit light of a particular wavelength or range of wavelengths. As such, the invention is not limited to phosphor based wavelength conversion components unless claimed as such.

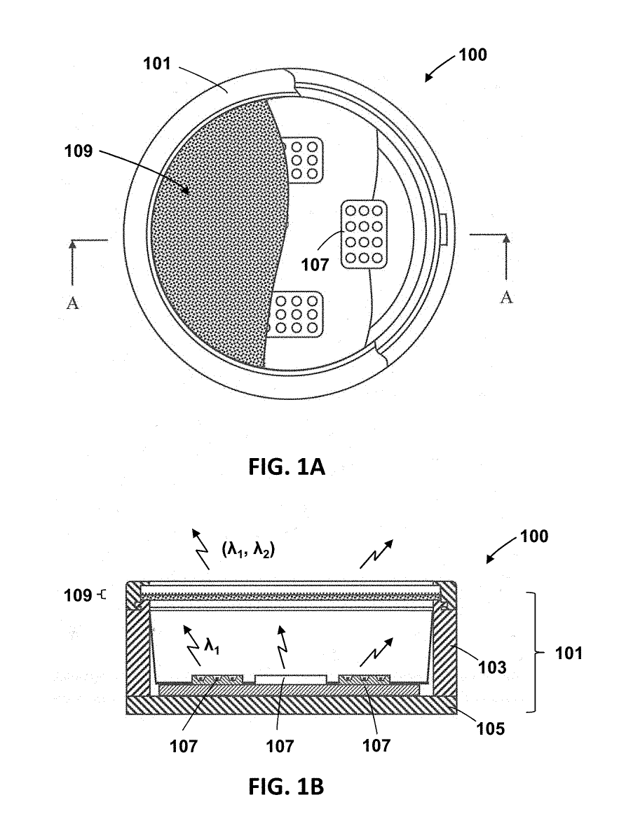

FIGS. 1A and 1B illustrate a schematic partial cutaway plan and section views of an example of a known light emitting device 100 that utilizes remote wavelength conversion. The device 100 comprises a hollow cylindrical body 101 with a base 105 and sidewalls 103. The device 100 further comprises a plurality of blue light emitting LEDs (blue LEDs) 107 that are mounted to the base 105 of the device 100. The LEDs 107 may be configured in various arrangements.

The device 100 further comprises a wavelength conversion component 109 that is positioned remotely to the LEDs 107. The wavelength conversion component 109 is operable to absorb a proportion of the blue light λ₁ generated by the LEDs 107 and convert it to light of a different wavelength λ₂ by a process of photoluminescence. The emission product of the device 100 comprises the combined light of wavelengths λ₁, λ₂ generated by the LEDs 107 and the wavelength conversion component 109. Light generated by the wavelength conversion component 109 refers to the emitted light resulting from conversion of the LED light into light of a different wavelength through photoluminescence.

The wavelength conversion component 109 may comprise phosphor material. In this situation, the color of the emission product produced by the wavelength conversion component will depend on the phosphor material composition and the quantity of phosphor material per unit area in the wavelength conversion component.

The typical light emitting device 100 suffers from undesirable dimming characteristics for certain lighting applications. Whereas some incandescent light bulbs, as described above, are capable of generating light that ranges from a warm yellowish white to a warmer orangeish white, the typical light emitting device 100 does not exhibit these same characteristics. This is because the color temperature of an incandescent light bulb changes in response to the power provided to the bulb whereas the correlated color temperature (CCT) of a typical light emitting device 100 changes in response to variations in photo-luminescent material of the wavelength conversion component 109. Because the photo-luminescent material of the wavelength conversion component 109 is fixed, when the output power of the LEDs 107 in a typical device 100 is lowered, the intensity of the emission product changes, but the correlated color temperature remains the same. Thus, rather than seeing the CCT of the device 100 vary from a warm yellowish white color to a warmer orangeish white color as output power to the LEDs 107 is lowered, the CCT varies from an intense blueish white to a less intense blueish white. For certain applications, this type of color variation with respect to output power is undesirable. Instead, a color variation that more closely resembles that of the dimmable incandescent light bulb described above may be desired.

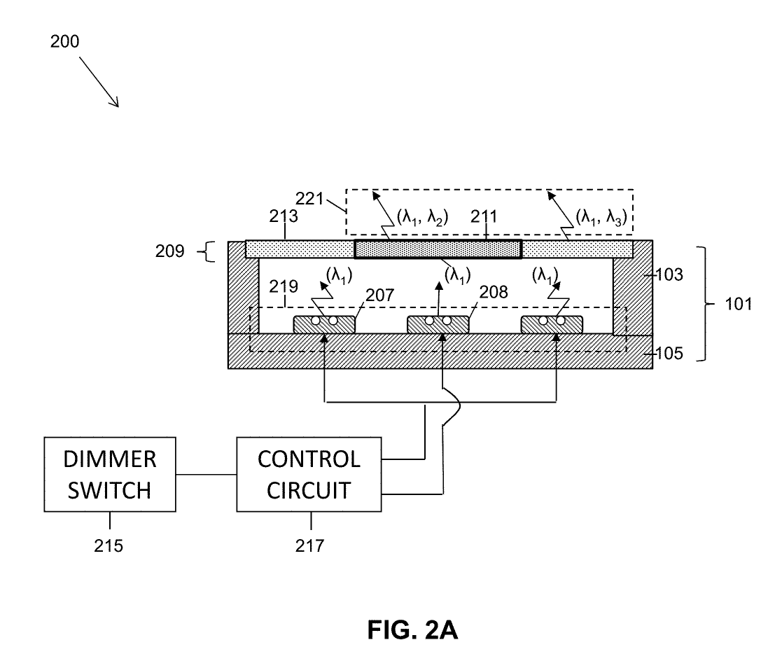

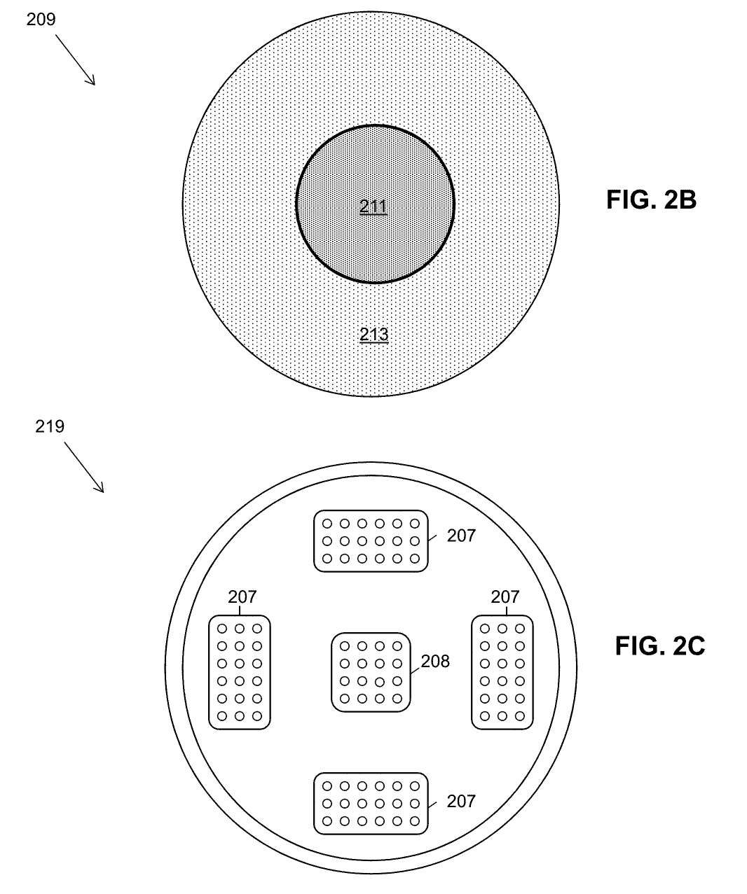

FIGS. 2A, 2B, and 2C illustrate a tunable light emitting device 200 that utilizes remote wavelength conversion in accordance with some embodiments. FIGS. 2A, 2B, and 2C are to be viewed together, where FIG. 2A illustrates a sectional view of the light emitting device 200, where FIG. 2B illustrates a top view of a wavelength conversion component 209 of the light emitting device 200, and where FIG. 2C illustrates a top view of an arrangement of a plurality of LEDs 219 of the light emitting device 200.

The device 200 comprises a hollow cylindrical body 101 with a base 103 and sidewalls 105, as described above with respect to FIG. 1. The device 200 may further comprise a plurality of blue light emitting LEDs (blue LEDs) 219 that are mounted to the base 105 of the device 200. Typically, the LEDs 219 comprise a light emitting diode (LED) such as an InGaN/GaN (indium gallium nitride/gallium nitride) based LED chip which is operable to generate blue light of wavelength 400 to 465 nm.

The device 200 further comprises a wavelength conversion component 209 that is positioned remotely to the LEDs 219. In some embodiments the wavelength conversion component 209 may include a wavelength conversion layer comprising photo-luminescent material situated on a light transmissive substrate (not shown). The wavelength conversion component 209 comprises a first region 211 composed of a first photo-luminescent material and a second region 213 composed of a second photo-luminescent material. The first and second photo-luminescent materials can comprise an inorganic or organic phosphor such as for example silicate-based phosphor of a general composition A₃Si(O,D)₅ or A₂Si(O,D)₄ in which Si is silicon, O is oxygen, A comprises strontium (Sr), barium (Ba), magnesium (Mg) or calcium (Ca) and D comprises chlorine (Cl), fluorine (F), nitrogen (N) or sulfur (S). Examples of silicate-based phosphors are disclosed in United States patents U.S. Pat. No. 7,575,697 B2 “Silicate-based green phosphors”, U.S. Pat. No. 7,601,276 B2 “Two phase silicate-based yellow phosphors”, U.S. Pat. No. 7,655,156 B2 “Silicate-based orange phosphors” and U.S. Pat. No. 7,311,858 B2 “Silicate-based yellow green phosphors”. The phosphor can also comprise an aluminate-based material such as is taught in co-pending patent application US2006/0158090 A1 “Novel aluminate-based green phosphors” and patent U.S. Pat. No. 7,390,437 B2 “Aluminate-based blue phosphors”, an aluminum-silicate phosphor as taught in co-pending application US2008/0111472 A1 “Aluminum-silicate orange-red phosphor” or a nitride-based red phosphor material such as is taught in co-pending United States patent application US2009/0283721 A1 “Nitride-based red phosphors” and International patent application WO2010/074963 A1 “Nitride-based red-emitting in RGB (red-green-blue) lighting systems”. It will be appreciated that the phosphor material is not limited to the examples described and can comprise any phosphor material including nitride and/or sulfate phosphor materials, oxy-nitrides and oxy-sulfate phosphors or garnet materials (YAG).

In some embodiments, the first region 211 may be located at the center of the wavelength conversion component 209 and the second region 213 may be located around the first region 211 as illustrated in FIG. 2B. In other embodiments, the first region 211 and second region 213 may be located differently within the wavelength conversion component 209. In some embodiments, the first region 211 may occupy 30% of the area of the wavelength conversion component 209 and the second region 213 may occupy 70% of the area of the wavelength conversion component 209. In other embodiments, the first region 211 and the second region 213 may occupy different areas of the wavelength conversion component. In some other embodiments, the wavelength conversion component may include more than a first region and a second region.

In some embodiments the LEDs 219 may be arranged such that a first set of LEDs 208 correspond to the first region 211 of the wavelength conversion component 209 and a second set of LEDs 207 correspond to a second region 213 of the wavelength conversion component 209 as illustrated in FIG. 2. In other embodiments, the plurality of LEDs 219 may be arranged uniformly or arranged in some other layout.

The wavelength conversion component 209 is operable to absorb a proportion of the blue light λ₁ generated by the LEDs 219 and convert it to light of a different wavelength by a process of photoluminescence (e.g., first region converts light to λ₂ and second region converts light to λ₃). Not all of the blue light λ₁ generated by the LEDs 219 is absorbed by the wavelength conversion component 209 and some of it is emitted. The emission product 221 of the device 200 thus comprises the combined light of wavelengths λ₁, λ₂, λ₃ generated by the LEDs 219 and the first 211 and second regions 213 of the wavelength conversion component 209. Light generated by a region 211, 213 of the wavelength conversion component 209 refers to the emitted light resulting from conversion of the LED light into light of a different wavelength through photoluminescence. Thus, light of wavelength λ₂ is generated by the first region 211, and light of wavelength λ₃ is generated by the second region 213. The CCT of the emission product 221 is thus a combination of the CCT of the light generated by the LED (λ₁), the CCT of the light (λ₂) generated by the first region 211, and the CCT of the light (λ₃) generated by the second region 213.

In some embodiments, the first region 211 of the wavelength conversion component 209 may include photo-luminescent material that generates light (λ₂) with a CCT corresponding to a warm yellowish white and the second region 213 of the wavelength conversion component 209 may include photo-luminescent material that generates light (λ₃) with a CCT corresponding to a cool blueish white. The emission product 221 of the device 200 in this example would be a combination of the warm yellowish white light generated by the first region 211, the cool blueish white light generated by the second region 213, and the blue light generated by the LEDs 219.

In some other embodiments, the first region 211 of the wavelength conversion component 209 may include a photo-luminescent material that generates light with a CCT corresponding to a cool blueish white and the second region 213 of the wavelength conversion component 209 may include photo-luminescent material that generates light with a CCT corresponding to warm yellowish white. The emission product 221 of the device 200 in this example would be a combination of the cool blueish whitelight generated by the first region 211, the warm yellowish white light generated by the second region 213, and the blue light generated by the LEDs 219.

A dimmer switch 215 may beoperably connected to a control circuit 217 which is operably connected to the plurality of LEDs 219. The dimmer switch 215 is configured to generate a continuous range of output powers to be used for tuning the light emitting device 200. The control circuit 217 is configured to translate the generated output power into an on/off arrangement and/or adjustable power arrangement for the plurality of LEDs 219.

While the variation in color temperature of an incandescent light bulb is directly related to the output power of the dimmer switch, the CCT of the emission product of the light emitting device 200 is not directly related to the output power of the dimmer switch 215. As such, the control circuit 217 must translate the output power of the dimmer switch 215 into a control arrangement for the plurality of LEDs 219 such that the device 200 dimming behavior resembles that of the dimmable incandescent light bulb described above.

Because the emission product 221 of the device is a combination of light (λ₁) generated by the LEDs 219 and light (λ₂, λ₃) generated by the first 211 and second regions 213 of the wavelength conversion component 209, the CCT of the emission product 221 can be changed by modifying the combination of light. Furthering the example discussed above, a CCT corresponding to a warm yellowish white color may be generated by having a larger portion of the emission product 221 emanate from the first region (e.g., region generating light with a CCT corresponding to a warm yellowish white) 211 and a smaller portion of the emission product emanate from the second region (e.g., region generating light with a CCT corresponding to a cool blueish white) 213. A CCT corresponding to a cool bluish white color may be generated by having a smaller portion of the emission product 221 emanate from the first region 211 and a larger portion of the emission product 221 emanate from the second region 213.

Because the composition, size, and location of the first region 211 and the second region 213 of the wavelength conversion component 209 are fixed, the combination of the emission product 221 may be modified, for example, by altering the on/off configuration of the plurality of LEDs 219. Thus, the CCT of the emission product 221 may grow closer to a warm yellowish color as the second set of LEDs 207 corresponding to the second region 213 of the wavelength conversion component 209 are turned off while the first set of LEDs 208 corresponding to the first region 211 of the wavelength conversion component 208 remain on. In some embodiments, the CCT of the emission product 221 may correspond to a cool bluish white color when the entirety of the plurality of LEDs 219 is turned on and shift towards a warm yellowish white color as the second set of LEDs 207 corresponding to the second region (e.g., region generating light with a CCT corresponding to a cool blueish white) 213 of the wavelength conversion component 209 are turned off

The CCT of the emission product 221 may also shift from a warm yellowish white color to a cool bluish white color as the second set of LEDs 207 corresponding to the second region 213 of the wavelength conversion component 209 are turned on. In some embodiments, the CCT of the emission product 221 may correspond to a warm yellowish white color when only the first set of LEDs 208 corresponding to the first region (e.g., region generating light with a CCT corresponding to a warm yellowish white) 211 is turned on and shift towards a cool bluish white color as the second set of LEDs 207 corresponding to the second region (e.g., region generating light with a CCT corresponding to a cool blueish white) 213 of the wavelength conversion component 209 are turned on.

Thus by configuring the control circuit 217 of the light emitting device 200 to translate output power of the dimmer switch 215 into a corresponding on/off configuration of the plurality of LEDs 219, the light emitting device 200 may be tuned like a typical incandescent light bulb, while also providing a significantly larger CCT range for the emission product when compared to a typical incandescent light bulb. Alternatively, instead of an on/off control, individual power levels are adjusted by control circuit 217 to the different sets 207 and 208 of LEDs, so that a selected ratio of the emissions from the different regions 211 and 213 is obtained to obtain a desired CCT of the emission product 221. In this approach, the CCT of the emission product 221 correspond to a cool bluish white color or a warm yellowish white color depending upon the relative amounts of power that are provided to the first set of LEDs 208 and the second set of LEDs 207.

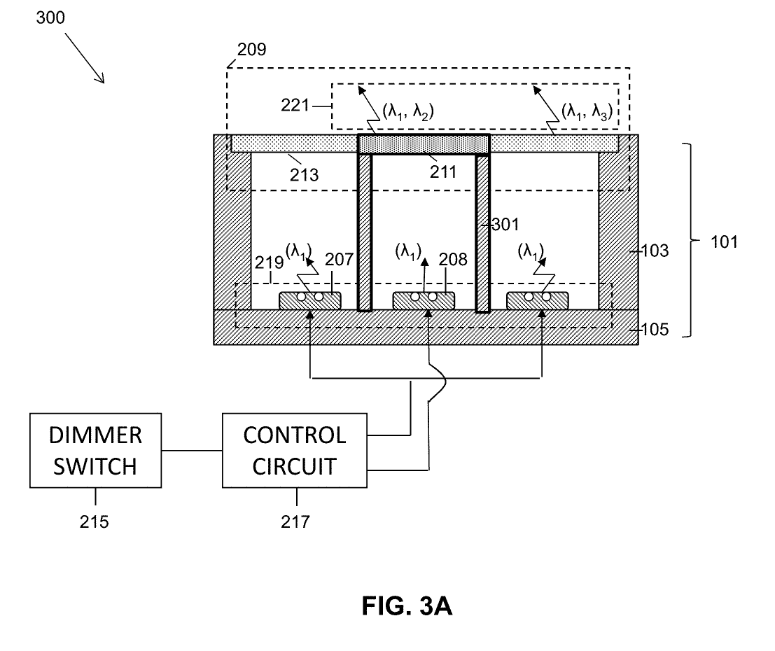

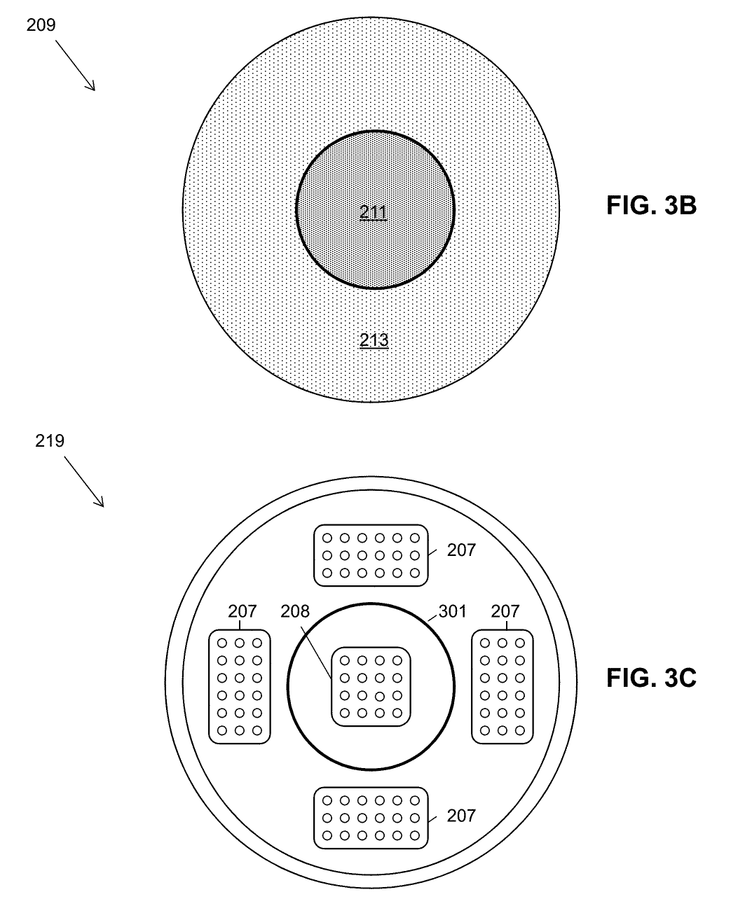

FIGS. 3A, 3B, and 3C illustrate a tunable light emitting device 300 that utilizes remote wavelength conversion in accordance with some embodiments. FIGS. 2A, 2B, and 2C are to be viewed together, where FIG. 3A illustrates a sectional view of the light emitting device 300, where FIG. 3B illustrates a top view of a wavelength conversion component 209 of the light emitting device 300, and where FIG. 3C illustrates a top view of an arrangement of a plurality of LEDs 219 of the light emitting device 300.

The light emitting device 300 of FIGS. 3A, 3B, and 3C operates substantially the same as the light emitting device of FIGS. 2A, 2B, and 2C. For purposes of discussion, only features of the light emitting device 300 of FIG. 3A that are new relative to the embodiments of FIG. 2A will be described.

The light emitting device 300 of FIGS. 3A, 3B, and 3C includes a cylindrical wall 301 to separate the LEDs corresponding to the first region 208 from the LEDs corresponding to the second region 207. By introducing a cylindrical wall 301 between the LEDs 207, 208 the light emitting device 300 may ensure that the light emitted by the LEDs 208 corresponding to the first region 211 will only irradiate the first region 211 of the wavelength conversion component 209 and the light emitted by the LEDs 207 corresponding to the second region 213 will only irradiate the second region 213 of the wavelength conversion component 209. The cylindrical wall 301 allows the wavelength conversion component 209 to be located at a greater distance from the plurality of LEDs 219, without creating interference between light generated by the LEDs 208 corresponding to the first region 211 and light generated by the LEDs 207 corresponding to the second region.

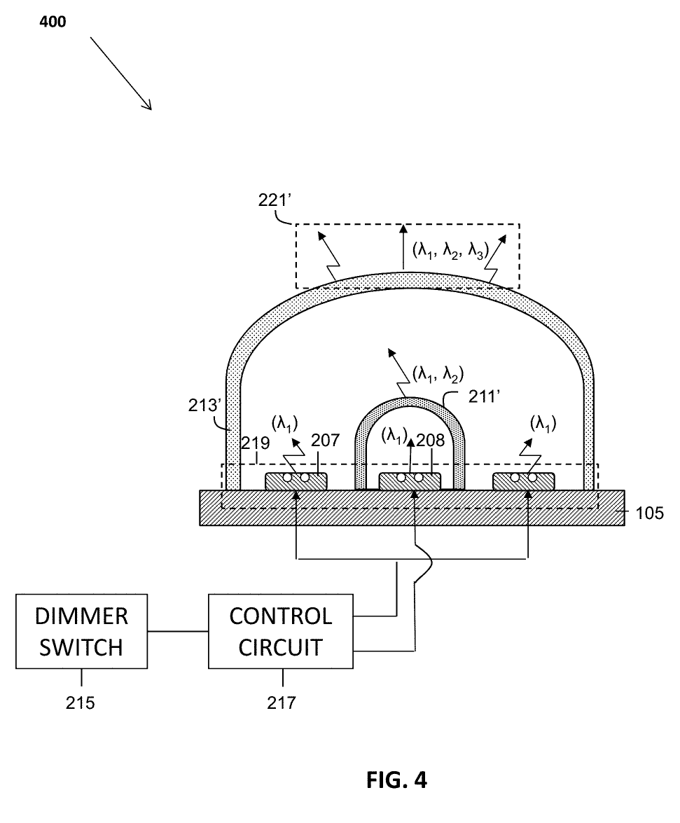

FIG. 4 illustrates a sectional view of a tunable light emitting device 400 that utilizes remote wavelength conversion in accordance with some other embodiments. The device 400 may comprise a plurality of blue light emitting LEDs (blue LEDs) 219 that are mounted to the base 105 of the device 400.

The device 400 includes a first wavelength conversion component 211′ comprising a first photo-luminescent material remote to the LEDs 219 and a second wavelength conversion component 213′ comprising a second photo-luminescent material also remote to the LEDs 219. The first and second photo-luminescent materials can comprise an inorganic or organic phosphor such as those described above with respect to FIGS. 2A, 2B, and 2C.

The first wavelength conversion component 211′ may have a three-dimensional configuration (e.g., elongated dome shaped and/or ellipsoidal shell) and enclose a first set of LEDs 208. The second wavelength conversion component 213′ may have also have a three-dimensional configuration (e.g., elongated dome shaped and/or ellipsoidal shell) and enclose a second set of LEDs 207, the first wavelength conversion component 211′, and the first set of LEDs 208.

The LEDs 219 may be arranged such that the first set of LEDs 208 correspond to the first wavelength conversion component 211′ and the second set of LEDs 207 correspond to the second wavelength conversion component 213′ as illustrated in FIG. 4.

The first wavelength conversion component 211′ is operable to absorb substantially all of the blue light λ₁ generated by the first set of LEDs 208 and convert it to light λ₂ of a different wavelength by a process of photoluminescence. However, not all of the blue light λ₁ generated by the first set of LEDs 208 is absorbed by the first wavelength conversion component 211′ and a small amount of it is emitted. Thus, the emission product of the first wavelength conversion component 211′ is the light λ₂ generated by the first wavelength conversion component 211′, and the small amount light λ₁ generated by the first set of LEDs 208 that is transmitted by the first wavelength conversion component 211′.

The second wavelength conversion component 213′ is operable to substantially absorb all of the blue light λ₁ generated by the second set of LEDs 207 and convert it to light λ₃ of a different wavelength by a process of photoluminescence. However, not all of the blue light λ₁ generated by the second set of LEDs 207 is absorbed by the second wavelength conversion component 213′ and small amount of it is emitted. A proportion of the small amount of light λ₁ generated by the first set of LEDs 208 that is transmitted by the first wavelength conversion component 211′ is absorbed by the second wavelength conversion component 213′ and converted into light λ₃ of a different wavelength by a process of photoluminescence. A proportion of the small amount of light λ₁ generated by the first set of LEDs 208 that is transmitted by the first wavelength conversion component 211′ is transmitted by the second wavelength conversion component 213′. The light λ₂ generated by the first wavelength conversion component 211′ is transmitted by the second wavelength conversion component 213′. The emission product 221′ of the device 400 thus comprises the combined light of wavelengths λ₁, λ₂, λ₃ generated by the LEDs 219 and the first 211′ and second 213′ wavelength conversion components.

Light generated by a wavelength conversion component 211′, 213′ refers to the emitted light resulting from conversion of the LED light into light of a different wavelength through photoluminescence. Thus, light of wavelength λ₂ is generated by the first wavelength conversion component 211′ and light of wavelength λ₃ is generated by the second wavelength conversion component 213′. The CCT of the emission product 221′ is thus a combination of the CCT of the light generated by the LEDs (λ₁), the CCT of the light (λ₂) generated by the first wavelength conversion component 211′, and the CCT of the light (λ₃) generated by the second wavelength conversion component 213′.

In some embodiments, the first wavelength conversion component 211′ may include photo-luminescent material that generates light (λ₂) with a CCT corresponding to a warm yellowish white and the second wavelength conversion component 213′ may include photo-luminescent material that generates light (λ₃) with a CCT corresponding to a cool blueish white. The emission product 221′ of the device 400 in this example would be a combination of the warm yellowish white light generated by the first wavelength conversion component 211′, the cool blueish white light generated by the second wavelength conversion component 213′, and the blue light generated by the LEDs 219.

The device 400 may further comprise a dimmer switch 215 operably connected to a control circuit 217 which is operably connected to the plurality of LEDs 219. The dimmer switch 215 is configured to generate a continuous range of output powers to be used for tuning the light emitting device 400. The control circuit 217 is configured to translate the generated output power into an on/off arrangement of the plurality of LEDs 219.

Because the emission product 221′ of the device 400 is a combination of light (λ₁) generated by the LEDs 219 and light (λ₂, λ₃) generated by the first 211′ and second 213′ wavelength conversion components, the CCT of the emission product 221′ can be changed by modifying the combination of light. A CCT corresponding to a warm yellowish white color may be generated by having a larger portion of the emission product 221′ emanate from the first wavelength conversion component (e.g., component generating light with a CCT corresponding to a warm yellowish white) 211′ and a smaller portion of the emission product emanate from the second wavelength conversion component (e.g., component generating light with a CCT corresponding to a cool blueish white) 213′. A CCT corresponding to a cool bluish white color may be generated by having a smaller portion of the emission product 221′ emanate from the first wavelength conversion component 211′ and a larger portion of the emission product 221′ emanate from the second wavelength conversion component 213′.

Because the composition, size, and location of the first wavelength conversion component 211′ and the second wavelength conversion component 213′ are fixed, the combination of the emission product 221′ may only be modified by altering the on/off configuration of the plurality of LEDs 219. Thus, the CCT of the emission product 221′ may grow closer to a warm yellowish color as the second set of LEDs 207 corresponding to the second wavelength conversion component 213′ are turned off while the first set of LEDs 208 corresponding to the first the wavelength conversion component 211′ remain on. In some embodiments, the CCT of the emission product 221′ may correspond to a cool bluish white color when the entirety of the plurality of LEDs 219 is turned on and shift towards a warm yellowish white color as the second set of LEDs 207 corresponding to the second wavelength conversion component (e.g., component generating light with a CCT corresponding to a cool blueish white) 213′ are turned off.

The CCT of the emission product 221′ may also shift from a warm yellowish white color to a cool bluish white color as the second set of LEDs 207 corresponding to the second wavelength conversion component 213′ are turned on. In some embodiments, the CCT of the emission product 221′ may correspond to a warm yellowish white color when only the first set of LEDs 208 corresponding to the first wavelength conversion component (e.g., component generating light with a CCT corresponding to a warm yellowish white) 211′ is turned on and shift towards a cool bluish white color as the second set of LEDs 207 corresponding to the second wavelength conversion component (e.g., component generating light with a CCT corresponding to a cool blueish white) 213′ are turned on.

Thus by configuring the control circuit 217 of the light emitting device 400 to translate output power of the dimmer switch 215 into a corresponding on/off configuration of the plurality of LEDs 219, the light emitting device 400 may be tuned like a typical incandescent light bulb, while also providing a significantly larger CCT range for the emission product when compared to a typical incandescent light bulb.

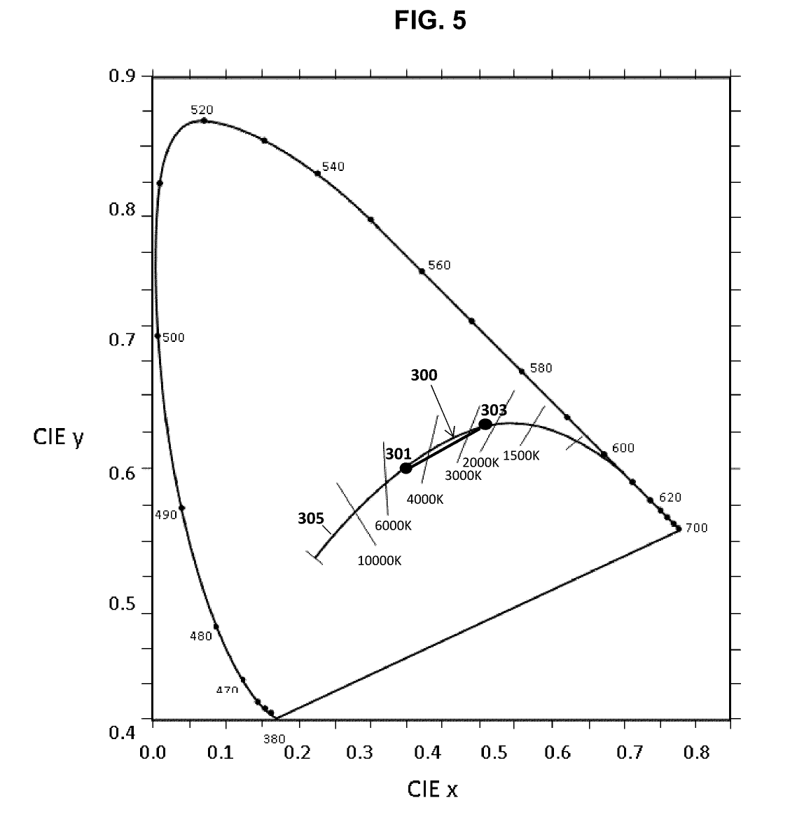

FIG. 5 illustrates a CIE (Commission Internationale de l'Eclairage) 1931 chromaticity diagram illustrating color tuning for the device of FIGS. 2A, 2B, and 2C. Curve 305 is a blackbody curve illustrating an absolute range of CCT corresponding to white light (e.g., blueish white light to yellowish white light). Line 300 illustrates the range of CCT corresponding to an emission product of the light emitting device described in FIGS. 2A, 2B, 2C, 3A, 3B, 3C, and 4. Point 301 indicates the CCT (e.g., 5000K) of an emission product corresponding to cool blueish white light that occurs when the emission product includes only light generated by the second region 213 of the wavelength conversion component 209 (as in FIGS. 2A, 2B, 2C, 3A, 3B, and 3C) or only light generated by the second wavelength conversion component 213′ (as in FIG. 4). Point 303 illustrates the CCT (e.g., 2700K) of an emission product corresponding to warm yellowish white light that occurs when the emission product includes only light generated 211 by the first region 211 of the wavelength conversion component 209 (as in FIGS. 2A, 2B, 2C, 3A, 3B, and 3C) or only light generated by the first wavelength conversion component 211′ (as in FIG. 4). The tunable light emitting devices 200, 300, 400 of FIGS. 2A, 2B, 2C, 3A, 3B, and 3C, and 4 can be configured to produce an emission product that ranges in CCT from point 301 to point 303 by adjusting an on/off arrangement of the LEDs 207, 208. While line 300 doesn't lie on the blackbody curve 305, it is significantly close enough to the blackbody curve 305 that the range of CCT associated with line 300 corresponds to light that appears white (e.g., blueish white to yellowish white).

Additionally, because the first region 211 of wavelength conversion component 209 (as in FIGS. 2A, 2B, 2C, 3A, 3B, and 3C) or the first wavelength conversion component 211′ (as in FIG. 4) and the second region 213 of the wavelength conversion component 209 (as in FIGS. 2A, 2B, 2C, 3A, 3B, and 3C) or the second wavelength conversion component 213′ (as in FIG. 4) both generate light with a CCT corresponding to a “white” color (e.g., lies on line 300), there is no risk of the control circuit 217 creating an emission product 221, 221′ for the light emitting device 200, 300, 400 with a CCT corresponding to a “non-white” color (e.g., does not lie on line 300). This is in contrast to other tunable systems that utilize an amber or red LED to create this dimming capability. In those systems, variations in the control circuit may lead to an emission product with a CCT that deviates from line 300, resulting in an emission product that may have a “non-white” color.

Furthermore, although the above embodiments describe a tunable light emitting device with an emission product corresponding to a CCT that ranges from warm yellowish (e.g., 2700K) light to cool blueish white light (e.g., 5000K), it is important to note that the tunable light emitting device may be configured to generate an emission product corresponding to a CCT with a different range.

Additionally, while the above embodiments illustrate a light emitting device utilizing a wavelength conversion component with two regions or two wavelength conversion components, it is important to note that in some other embodiments the light emitting device may utilize a wavelength conversion component with more than two regions or may utilize more than two wavelength conversion components. However, a light emitting device utilizing a wavelength conversion component with two regions or two wavelength conversion components may be easier to implement than a light emitting device utilizing a wavelength conversion component with more than two regions or more than two wavelength conversion components.

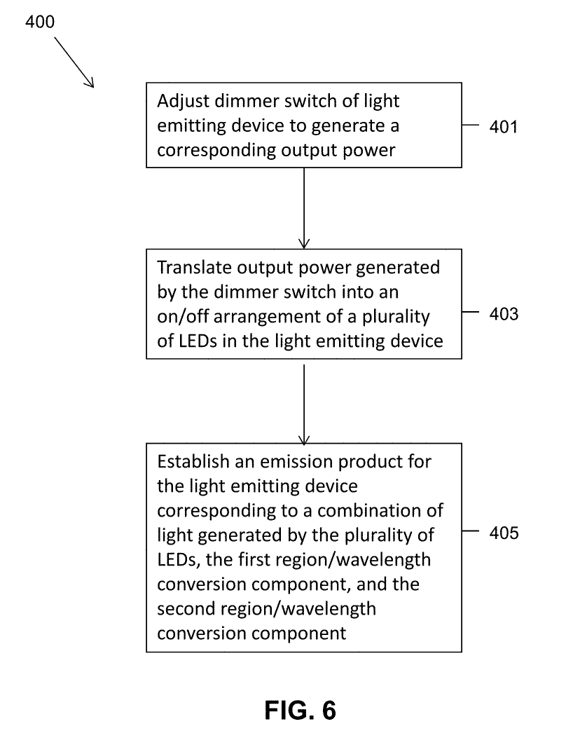

FIG. 6 illustrates a flowchart of a method 400 for tuning a light-emitting device in accordance with some embodiments. A light emitting device may generate an emission product with a CCT corresponding to a certain color. A dimmer switch of the light emitting device may then be adjusted to generate a corresponding output power as shown in step 401. For example, the user of the light emitting device may adjust the dimmer switch to generate a large output power when an output with a CCT corresponding to a cooler bluish white is desired. Alternatively, the user of the light emitting device may adjust the dimmer switch to generate a small output power when an output with a CCT corresponding to a warmer yellowish white is desired.

The output power generated by the dimmer switch may then be translated by a control circuit into an on/off arrangement of a plurality of LEDs in the light emitting device as shown in step 403. In some embodiments, the light emitting device may comprise a first set of LEDs corresponding to a first region of the wavelength conversion component (e.g., region generating light with a CCT corresponding to a warm yellowish white) or a first wavelength conversion component (e.g., component generating light with a CCT corresponding to warm yellowish white) and a second set of LEDs corresponding to a second region of the wavelength conversion component (e.g., region generating light with a CCT corresponding to a cool blueish white) or a second wavelength conversion component (e.g., component generating light with a CCT corresponding to cool blueish white). An on/off arrangement of an emission product with a CCT corresponding to cool blueish white may have both sets of LEDs on. An on/off arrangement of an emission product with a CCT corresponding to warm yellowish white may have only the first set of LEDs on or the first set of LEDs and a small proportion of the second set on.

An emission product for the light emitting device corresponding to a combination of light generated by the plurality of LEDs and light generated by a first region of the wavelength conversion component or a first wavelength conversion component and a second region of the wavelength conversion component or a second wavelength conversion component may then be established as shown in step 405. As already mentioned above, the emission product may have a CCT corresponding to an on/off arrangement of the plurality of LEDs in the light emitting device. Thus, a sliding scale of colors between cool bluish white and warm yellowish white may be established based on the on/off arrangement determined in step 403.

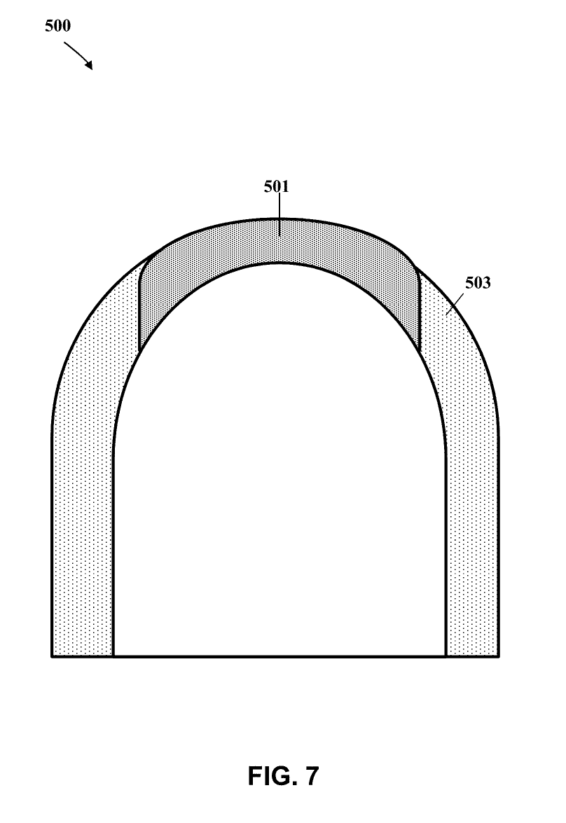

As previously disclosed in FIG. 4, it is possible for the wavelength conversion component to have a three-dimensional configuration for different applications. FIG. 7 illustrates a cross-sectional view of an alternative wavelength conversion component 500 in accordance with some embodiments, which has a three-dimensional version of the configuration disclosed in FIGS. 2A and 2B. For purposes of discussion, only features of the wavelength conversion component 500 of FIG. 7 that are new relative to the embodiments of FIGS. 2A and 2B will be described.

Whereas the wavelength conversion component 209 in FIGS. 2A and 2B has a two-dimensional shape (e.g., is substantially planar), the wavelength conversion component 500 of FIG. 7 has a three-dimensional shape (e.g., elongated dome shaped and/or ellipsoidal shell). The three-dimensional wavelength conversion component 500 in FIG. 7 includes a three-dimensional first region 501 and a three-dimensional second region 503 rather than a planar first region and a planar second region.

Configuring the wavelength conversion component 500 to be three-dimensional rather than two-dimensional may be useful for applications where it is necessary for light emitted from the light emitting device to be spread over a larger solid angle.

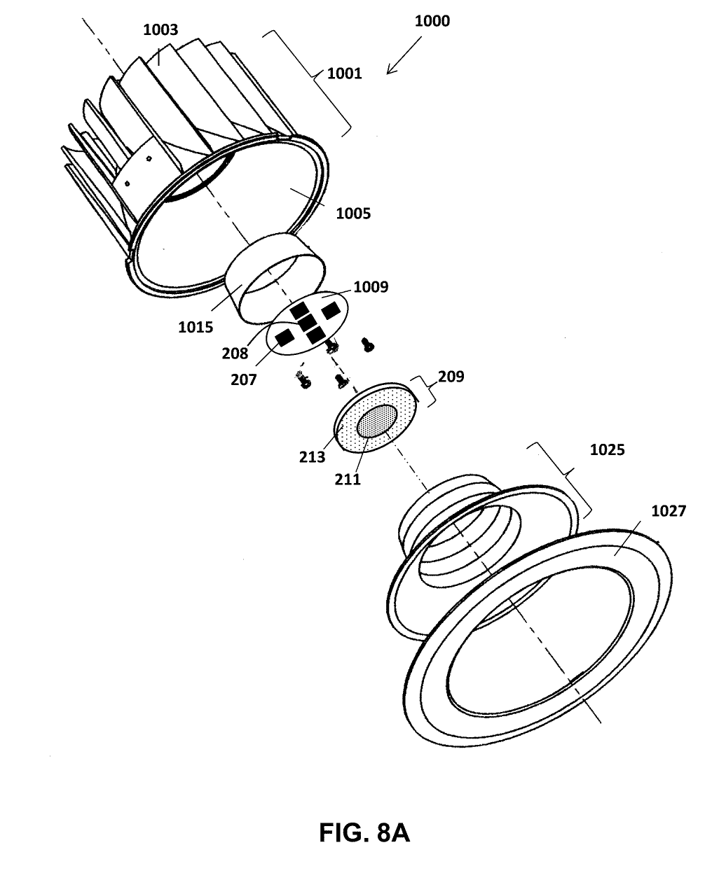

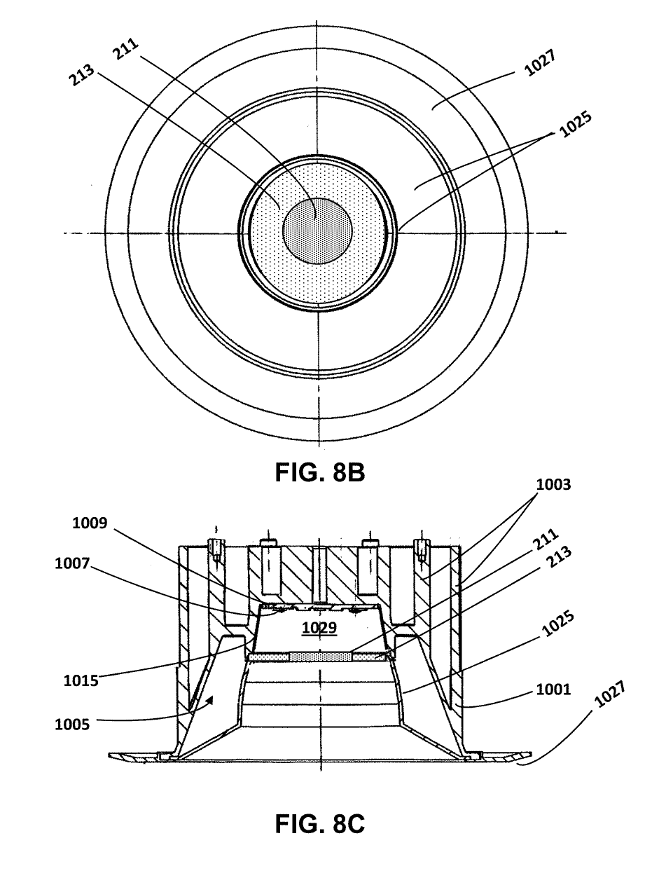

FIGS. 8A, 8B, and 8C illustrate an example of an application of a wavelength conversion component in accordance with some embodiments of the invention. FIGS. 8A, 8B, and 8C illustrates a tunable LED downlight 1000 that utilizes remote wavelength conversion in accordance with some embodiments. FIG. 8A is an exploded perspective view of the LED downlight 1000, FIG. 8B is an end view of the downlight 1000, and FIG. 8C is a sectional view of the downlight 1000. The downlight 1000 is configured to generate light with an emission intensity of 650-700 lumens and a nominal beam spread of 60° (wide flood). It is intended to be used as an energy efficient replacement for a conventional incandescent six inch downlight.

The downlight 1000 comprises a hollow generally cylindrical thermally conductive body 1001 fabricated from, for example, die cast aluminum. The body 1001 functions as a heat sink and dissipates heat generated by the light emitters 207, 208. To increase heat radiation from the downlight 1000 and thereby increase cooling of the downlight 1000, the body 1001 can include a series of latitudinal spirally extending heat radiating fins 1003 located towards the base of the body 1001. To further increase the radiation of heat, the outer surface of the body can be treated to increase its emissivity such as for example painted black or anodized. The body 1001 further comprises a generally frustoconical (i.e. a cone whose apex is truncated by a plane that is parallel to the base) axial chamber 1005 that extends from the front of the body a depth of approximately two thirds of the length of the body. The form factor of the body 1001 is configured to enable the downlight to be retrofitted directly in a standard six inch downlighting fixture (can) as are commonly used in the United States.

Light emitters 207, 208, such as those described above in FIGS. 2A and 2B are mounted on a circular shaped MCPCB (Metal Core Printed Circuit Board) 1009. As is known an MCPCB comprises a layered structure composed of a metal core base, typically aluminum, a thermally conducting/electrically insulating dielectric layer and a copper circuit layer for electrically connecting electrical components in a desired circuit configuration. With the aid of a thermally conducting compound such as for example a standard heat sink compound containing beryllium oxide or aluminum nitride the metal core base of the MCPCB 1009 is mounted in thermal communication with the body via the floor of the chamber 1005. As shown in FIG. 5 the MCPCB 1009 can be mechanically fixed to the body floor by one or more screws, bolts or other mechanical fasteners.

The downlight 1000 further comprises a hollow generally cylindrical light reflective chamber wall mask 1015 that surrounds the light emitters 207, 208. The chamber wall mask 1015 can be made of a plastics material and preferably has a white or other light reflective finish. A wavelength conversion component 209, such as the one described above in FIG. 2A, may be mounted overlying the front of the chamber wall mask 1015 using, for example, an annular steel clip that has resiliently deformable barbs that engage in corresponding apertures in the body. The wavelength conversion component 209 is remote to the light emitters 207, 208.

The wavelength conversion component 209 comprises a first region 211 comprising a first photo-luminescent material and a second region 213 comprising a second photo-luminescent material. The first region 211 may be located at the center of the wavelength conversion component 209 and the second region 213 may be located around the first region 211. The first region 211 may include photo-luminescent material configured to generates light (λ₂) with a CCT corresponding to a warm yellowish white and the second region 213 may include photo-luminescent material configured to generate light (λ₃) with a CCT corresponding to a cool blueish white. The CCT of the emission product of the downlight 1000 is thus a combination of the CCT of the light generated by the light emitters (λ₁), the CCT of the light (λ₂) generated by the first region 211, and the CCT of the light (λ₃) generated by the second region 213.

The light emitters 207, 208 may be configured such that a first set 208 of light emitters corresponds to the first region 211 and a second set 207 of light emitters correspond to the second region 213. The downlight 1000 may further comprise a control circuit (not shown) configured to translate output power of a dimmer switch into a corresponding on/off configuration of the light emitters 207, 208. Thus by configuring the control circuit of the downlight to translate output power of the dimmer switch into a corresponding on/off configuration of the light emitters 207, 208, the downlight 1000 may be tuned like a typical incandescent light bulb, as discussed above in FIGS. 2A, 2B, 2C, 3A, 3B, and 3C.

The downlight 1000 further comprises a light reflective hood 1025 which is configured to define the selected emission angle (beam spread) of the downlight (i.e. 60° in this example). The hood 1025 comprises a generally cylindrical shell with three contiguous (conjoint) inner light reflective frustoconical surfaces. The hood 1025 is preferably made of Acrylonitrile butadiene styrene (ABS) with a metallization layer. Finally the downlight 1000 can comprise an annular trim (bezel) 1027 that can also be fabricated from ABS.

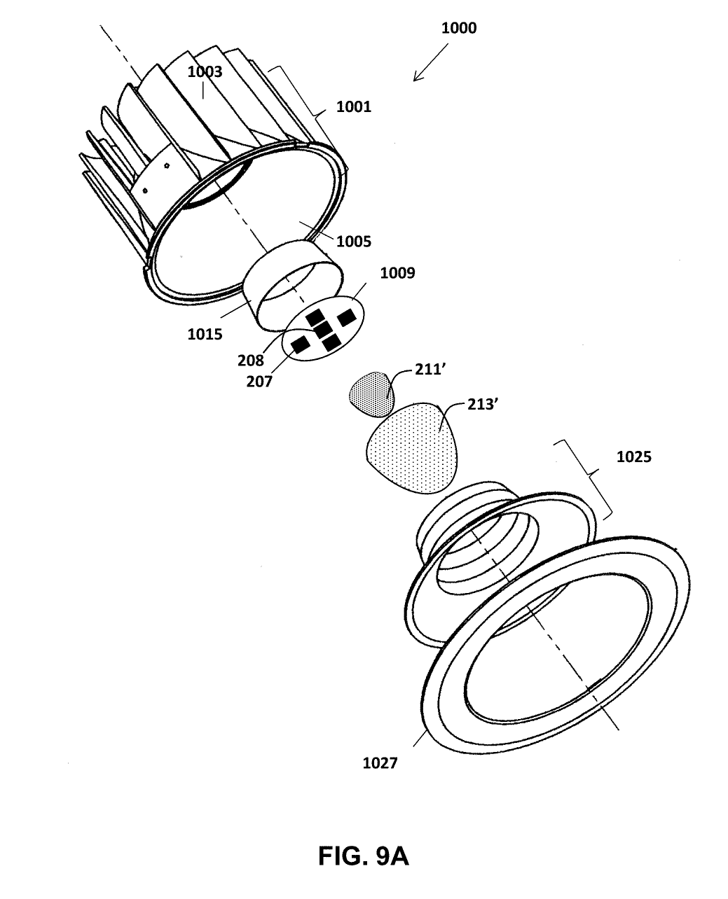

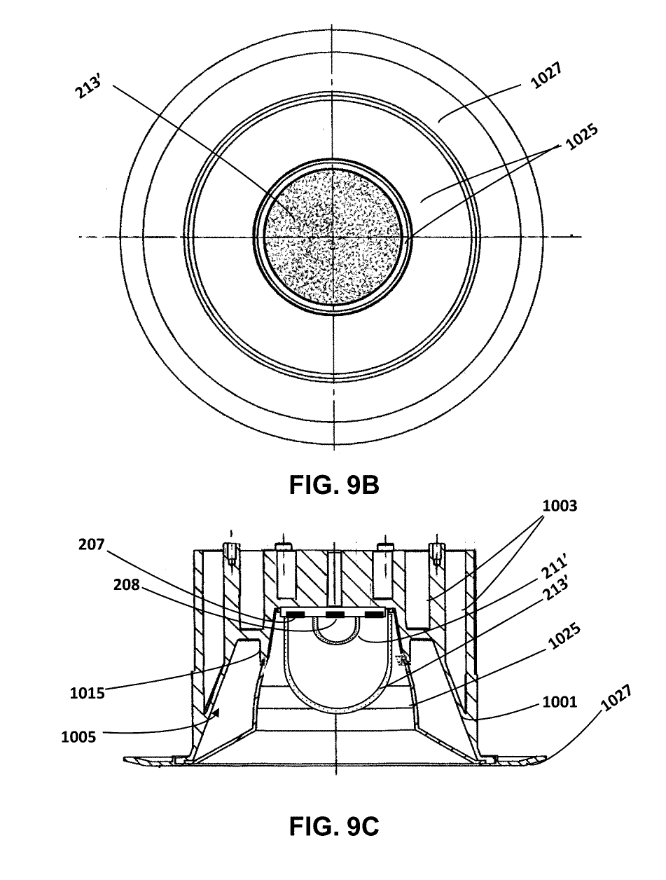

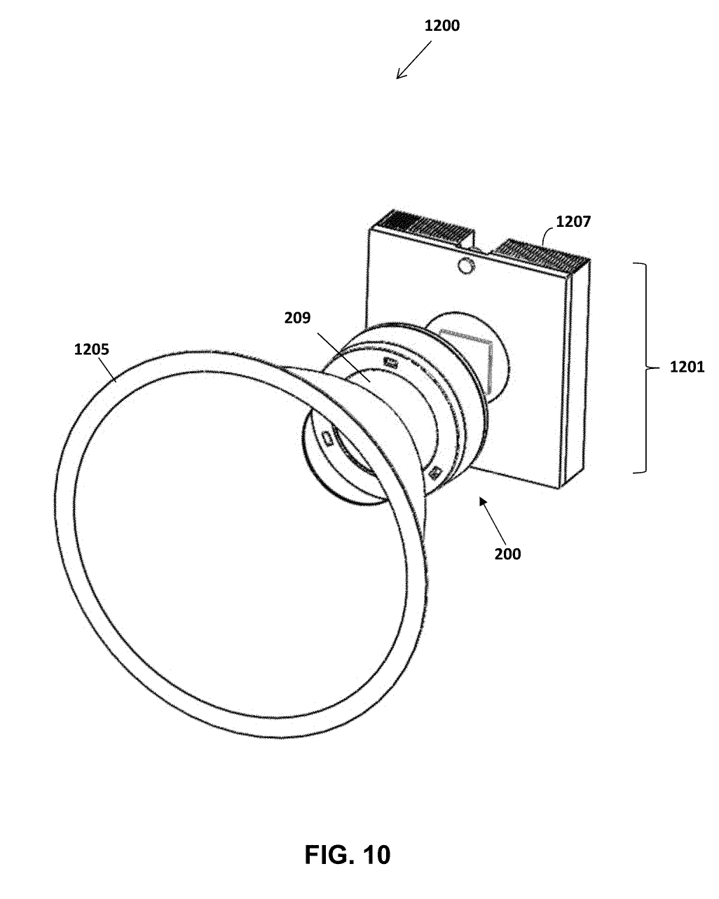

FIGS. 9A, 9B, and 9C illustrate another example of an application of a light emitting device in accordance with some embodiments. FIGS. 9A, 9B, and 9C illustrate a tunable LED downlight 1100 that utilizes remote wavelength conversion in accordance with some embodiments. FIG. 9A is an exploded perspective view of the LED downlight 1100, FIG. 9B is an end view of the downlight 1100, and FIG. 9C is a sectional view of the downlight 1100. The downlight 1100 is configured to generate light with an emission intensity of 650-700 lumens and a nominal beam spread of 60° (wide flood). It is intended to be used as an energy efficient replacement for a conventional incandescent six inch downlight.

The downlight 1100 of FIGS. 9A, 9B, and 9C is substantially the same as the downlight 1000 of FIGS. 8A, 8B, and 8C. For purposes of discussion, only features of the downlight 1100 that are new relative to the embodiments of FIGS. 8A, 8B, and 8C will be described.

Instead of a wavelength conversion component with two regions of two different photo-luminescent materials, the downlight 1100 in FIGS. 9A, 9B, and 9C includes a three-dimensional (e.g., elongated dome shaped and/or ellipsoidal shell) first wavelength conversion component 211′ comprising a first photo-luminescent material and a three-dimensional (e.g., elongated dome shaped and/or ellipsoidal shell) second wavelength conversion component 213′ comprising a second photo-luminescent material, such as those described above with respect to FIG. 4.

The light emitters 207, 208 may be configured such that a first set 208 of light emitters corresponds to and is enclosed by the first wavelength conversion component 211′ and a second set 207 of light emitters corresponds to and is enclosed by the second wavelength conversion component 213′. The downlight 1100 may further comprise a control circuit (not shown) configured to translate output power of a dimmer switch into a corresponding on/off configuration of the light emitters 207, 208. Thus by configuring the control circuit of the downlight to translate output power of the dimmer switch into a corresponding on/off configuration of the light emitters, the downlight 1100 may be tuned like a typical incandescent light bulb, as discussed above in FIG. 4.

FIG. 10 illustrates another example of an application of a wavelength conversion component in accordance with some embodiments. FIG. 10 illustrates an exploded perspective view of a tunable LED reflector lamp 1200 that utilizes remote wavelength conversion in accordance with some embodiments. The reflector lamp 1200 is configured to generate light with an emission intensity of 650-700 lumens and a nominal beam spread of 60° (wide flood). It is intended to be used as an energy efficient replacement for a conventional incandescent six inch downlight.

The reflector lamp 1200 comprises a generally rectangular thermally conductive body 1201 fabricated from, for example, die cast aluminum. The body 1201 functions as a heat sink and dissipates heat generated by the light emitting device 200, such as the one described above. To increase heat radiation from the reflector lamp 1200 and thereby increase cooling of the light emitting device 200, the body 1201 can include a series of heat radiating fins 1207 located on the sides of the body 1201. To further increase the radiation of heat, the outer surface of the body 1201 can be treated to increase its emissivity such as for example painted black or anodized. The body 1201 further comprises a thermally conductive pad that may be placed in contact with a thermally conductive base of the light emitting device 200. The form factor of the body 1201 is configured to enable the reflector lamp 1200 to be retrofitted directly in a standard six inch downlighting fixture (a “can”) as are commonly used in the United States.

A light emitting device 200 that includes a wavelength conversion component 209 such as the one described above with respect to FIGS. 2A, 2B, and 2C may be attached to the body 1201 such that the thermally conductive base of the light emitting device 200 may be in thermal contact with the thermally conductive pad of the body 1201. The light emitting device 200 may include a hollow cylindrical body with a base and sidewalls that is substantially the same as the cylindrical body described in FIGS. 2A, 2B, and 2C that is configured to house the wavelength conversion component 209. The light emitting device further includes light emitters (not shown), as described in FIGS. 2A, 2B, and 2C.

While not illustrated, the wavelength conversion component 209 may include a first region comprising a first photo-luminescent material and a second region comprising a second photo-luminescent material. The first region may be located at the center of the wavelength conversion component and the second region may be located around the first region, as described in FIGS. 2A, 2B, and 2C. The first region may include photo-luminescent material configured to generates light (λ₂) with a CCT corresponding to a warm yellowish white and the second region may include photo-luminescent material configured to generate light (λ₃) with a CCT corresponding to a cool blueish white. The CCT of the emission product of the reflector lamp 1200 is thus a combination of the CCT of the light generated by the light emitters (λ₁), the CCT of the light (λ₂) generated by the first region, and the CCT of the light (λ₃) generated by the second region.

The light emitters may be configured such that a first set of light emitters corresponds to the first region and a second set of light emitters correspond to the second region. The reflector lamp 1200 may further comprise a control circuit (not shown) configured to translate output power of a dimmer switch into a corresponding on/off configuration of the light emitters of the light emitting device 200. Thus by configuring the control circuit of the reflector lamp 1200 to translate output power of the dimmer switch into a corresponding on/off configuration of the light emitters, the reflector lamp 1200 may be tuned like a typical dimmable incandescent light bulb, as discussed above in FIGS. 2A, 2B, 2C, 3A, 3B, and 3C.

The reflector lamp 1200 further comprises a generally frustroconical light reflector 1205 having a paraboloidal light reflective inner surface which is configured to define the selected emission angle (beam spread) of the downlight (i.e. 60° in this example). The reflector 1205 is preferably made of Acrylonitrile butadiene styrene (ABS) with a metallization layer.

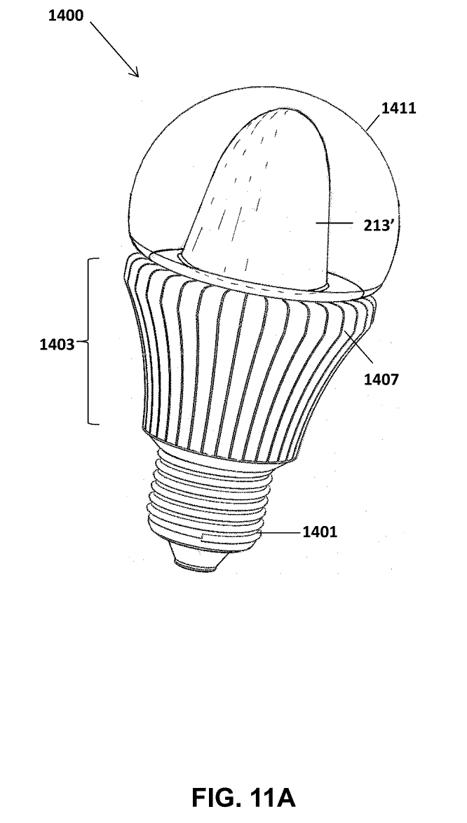

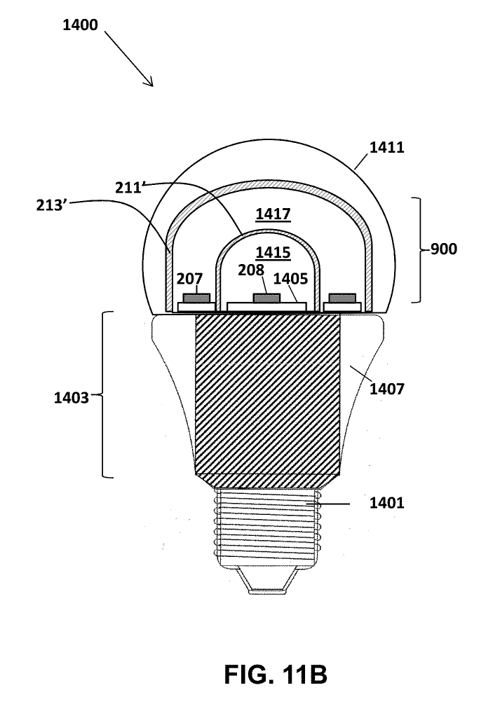

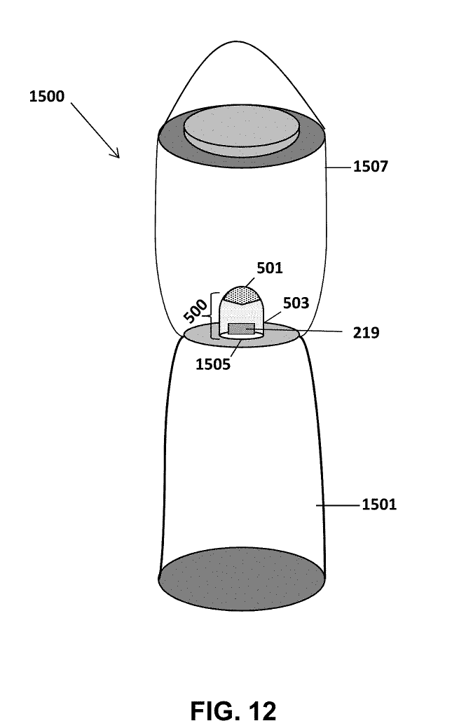

FIGS. 11A and 11B illustrate a perspective view and a cross-sectional view of an application of a light emitting device in accordance with some embodiments. FIGS. 12A and 12B illustrate a tunable LED light bulb that utilizes remote wavelength conversion. The LED light bulb 1400 is intended to be used as an energy efficient replacement for a conventional dimmable incandescent light bulb.

The light bulb 1400 comprises a screw base 1401 that is configured to fit within standard light bulb sockets, e.g. implemented as a standard Edison screw base. The light bulb 1400 may further comprise a thermally conductive body 1403 fabricated from, for example, die cast aluminum. The body 1403 functions as a heat sink and dissipates heat generated by the light emitters 207, 208, which are mounted on an MCPCB 1405. The MCPCB 1405 may be in thermal contact with the body 1403. To increase heat radiation from the light bulb 1400 and thereby increase cooling of the light bulb 1400, the body 1403 can include a series of latitudinal radially extending heat radiating fins 1407. To further increase the radiation of heat, the outer surface of the body 1403 can be treated to increase its emissivity such as for example painted black or anodized.

The light bulb 1400 in FIGS. 11A and 11B includes a three-dimensional (e.g., elongated dome shaped and/or ellipsoidal shell) first wavelength conversion component 211′ comprising a first photo-luminescent material and a three-dimensional (e.g., elongated dome shaped and/or ellipsoidal shell) second wavelength conversion component 213′ comprising a second photo-luminescent material, such as those described above with respect to FIG. 4.

The light emitters 207, 208 may be configured such that a first set 208 of light emitters corresponds to and is enclosed by the first wavelength conversion component 211′ and a second set 207 of light emitters corresponds to and is enclosed by the second wavelength conversion component 213′. The light bulb 1400 may further comprise a control circuit (not shown) configured to translate output power of a dimmer switch into a corresponding on/off configuration of the light emitters 207, 208. Thus by configuring the control circuit of the light bulb 1400 to translate output power of the dimmer switch into a corresponding on/off configuration of the light emitters 207, 208, the LED light bulb 1400 may be tuned like a typical dimmable incandescent light bulb, as discussed above in FIG. 4.

An envelope 1411 may extend around the upper portion of the LED light bulb 1400, enclosing the light emitters 207, 208 and the first and second wavelength conversion components 211′, 213′. The envelope 1411 is a light-transmissive material (e.g. glass or plastic) that provides protective and/or diffusive properties for the LED light bulb 1400.

FIG. 12 illustrates a perspective of another application of a wavelength conversion component in accordance with some embodiments. FIG. 12 illustrates a tunable LED lantern 1500 that utilizes remote wavelength conversion. The LED light lantern 1500 is intended to be used as an energy efficient replacement for conventional gas and fluorescent lanterns (e.g., camping lanterns).

The lantern 1500 comprises a generally cylindrical thermally conductive body 1501 fabricated from, for example, plastic material or pressed metal. The body 1501 further includes an internal heat sink which dissipates heat generated by the light emitters 219, which are mounted on a circular shaped MCPCB 1505. The MCPCB 1505 may be in thermal contact with the body 1501.

The lantern 1500 comprises a three-dimensional (e.g., elongated dome shaped and/or ellipsoidal shell) wavelength conversion component 500, such as the one described above in FIG. 7, that extends from the MCPCB 1505. The wavelength conversion component 500 may include a three-dimensional first region 501 comprising a first photo-luminescent material and a three-dimensional second region 503 comprising a second photo-luminescent material, as described in FIG. 7. The first region 501 may be located at the center of the wavelength conversion component 500 and the second region 503 may be located around the first region 501, as described in FIGS. 2A, 2B, and 2C. The first region 501 may include photo-luminescent material configured to generates light (λ₂) with a CCT corresponding to a warm yellowish white and the second region 503 may include photo-luminescent material configured to generate light (λ₃) with a CCT corresponding to a cool blueish white. The CCT of the emission product of the lantern 1500 is thus a combination of the CCT of the light generated by the light emitters (λ₁), the CCT of the light (λ₂) generated by the first region, and the CCT of the light (λ₃) generated by the second region.

The light emitters 219 may be configured such that a first set of light emitters corresponds to the first region 501 and a second set of light emitters correspond to the second region 503. The lantern 1500 may further comprise a control circuit (not shown) configured to translate output power of a dimmer switch into a corresponding on/off configuration of the light emitters 219. Thus by configuring the control circuit of the lantern 1500 to translate output power of the dimmer switch into a corresponding on/off configuration of the light emitters 219, the lantern 1500 may be tuned like a typical dimmable incandescent light bulb, as discussed above in FIGS. 2A, 2B, 2C, 3A, 3B, and 3C.

A light transmissive cover (e.g., plastic) 1507 may extend around the upper portion of the lantern, surrounding the light emitters 219 and the wavelength conversion component 500. The light transmissive cover 1507 comprises a light-transmissive material (e.g. glass or plastic) that provides protective and/or diffusive properties for the LED lantern 1500. The lantern 1500 may further comprise a lid that sits on top of the light transmissive cover 1507 to enclose the light emitters 219 and the wavelength conversion component 500.

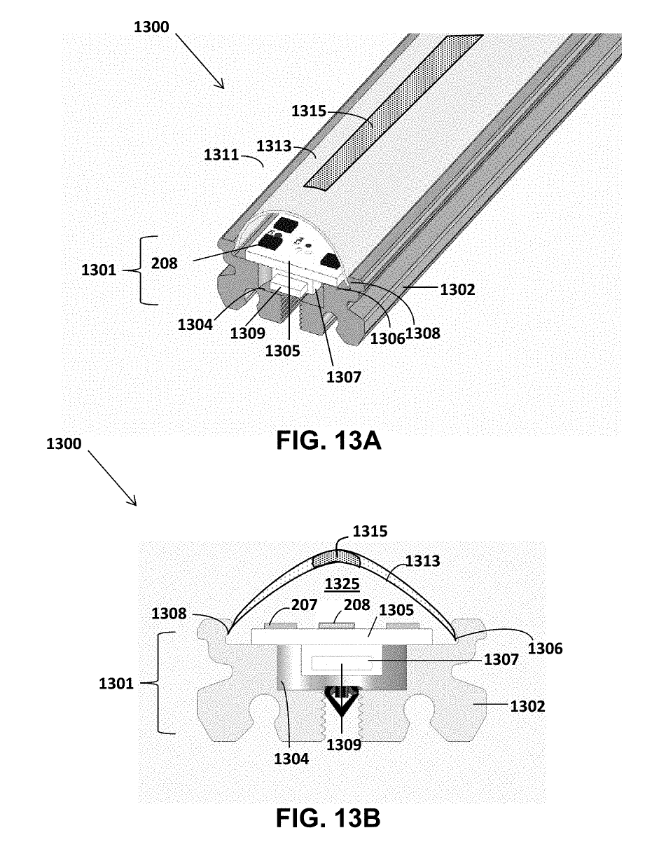

FIGS. 13A and 13B illustrate another example of an application of a wavelength conversion component in accordance with some embodiments. FIGS. 13A and 13B illustrate an LED linear lamp 1300 in accordance with some embodiments. FIG. 13A is a three-dimensional perspective view of the linear lamp 1300 and FIG. 13B is a cross-sectional view of the linear lamp 1300. The LED linear lamp 1300 is intended to be used as an energy efficient replacement for a conventional incandescent or fluourescent tube lamp.

The linear lamp 1300 comprises an elongated thermally conductive body 1301 fabricated from, for example, die cast aluminum. The form factor of the body 1301 is configured to be mounted with a standard linear lamp housing. The body 1301 further comprises a first recessed channel 1304, wherein a rectangular tube-like case 1307 containing some electrical components (e.g., electrical wires) of the linear lamp 1300 may be situated. The case 1307 may further comprise an electrical connector 1309 (e.g., plug) extending past the length of the body 1301 on one end, and a recessed complimentary socket (not shown) configured to receive a connector on another end. This allows several linear lamps 1300 to be connected in series to cover a desired area. Individual linear lamps 1300 may range from 1 foot to 6 feet in length.

The body 1301 functions as a heat sink and dissipates heat generated by the light emitters 207, 208, such as those described above in FIGS. 2A, 2B, and 2C. To increase heat radiation from the linear lamp 1300 and thereby increase cooling of the light emitters 207, 208, the body 1301 can include a series of heat radiating fins 1302 located on the sides of the body 1301. To further increase heat radiation from the linear lamp 1300, the outer surface of the body 1301 can be treated to increase its emissivity such as for example painted black or anodized.

Light emitters 207, 208 are mounted on a strip (rectangular shaped) MCPCB 1305 configured to sit above the first recessed channel 1304. The under surface of the MCPCB 1305 sits in thermal contact with a second recessed channel 1306 that includes inclined walls 1308.

A generally hemi-spherical elongate wavelength conversion component 1311 may be positioned remote to the light emitters 1307. The wavelength conversion component 1311 may be secured within the second recessed channel 1306 by sliding the wavelength conversion component 1311 under the inclined walls 1308 such that the wavelength conversion component 1311 engages with inclined walls 1308. The wavelength conversion component 1311 may also be flexibly placed under the inclined walls 1308 such that the wavelength conversion component 1311 engages with the inclined walls 1308.

The wavelength conversion component 1311 may include a first region 1315 comprising a first photo-luminescent material and a second region 1313 comprising a second photo-luminescent material. The first region 1315 may be located at the center of the wavelength conversion component 1311 and the second region 1313 may be located around the first region 1315. The first region 1315 may include photo-luminescent material configured to generates light (λ₂) with a CCT corresponding to a warm yellowish white and the second region 1313 may include photo-luminescent material configured to generate light (λ₃) with a CCT corresponding to a cool blueish white. The CCT of the emission product of the linear lamp 1300 is thus a combination of the CCT of the light generated by the light emitters 207, 208 (λ₁), the CCT of the light (λ₂) generated by the first region 1315, and the CCT of the light (λ₃) generated by the second region 1313.

The light emitters 207, 208 may be configured such that a first set of light emitters 207 corresponds to the first region 1315 and a second set of light emitters 208 correspond to the second region 1313. The linear lamp 1300 may further comprise a control circuit (not shown) configured to translate output power of a dimmer switch into a corresponding on/off configuration of the light emitters 207, 208. Thus by configuring the control circuit of the linear lamp 1300 to translate output power of the dimmer switch into a corresponding on/off configuration of the light emitters 207, 208, the linear lamp 1300 may be tuned like a typical incandescent light bulb, as discussed above.

In alternative embodiments, the wavelength conversion component of the linear lamp may be configured in the shape of a generally planar strip. In such embodiments, it will be appreciated that the second recessed channel may instead have vertical walls that extend to allow the wavelength conversion component to be received by the second recessed channel.

The above applications of light emitting devices describe a remote wavelength conversion configuration, wherein one or more wavelength conversion components are remote to one or more light emitters. The wavelength conversion components and body of those light emitting devices define one or more interior volumes wherein the light emitters are located. The interior volumes may also be referred to as light mixing chambers. For example, in the downlight 1000 of FIGS. 8A, 8B, 8C an interior volume 1029 is defined by the wavelength conversion component 209, the light reflective chamber mask 1015, and the body of the downlight 1001. In the linear lamp 1300 of FIGS. 13A and 13B, an interior volume 1325 is defined by the wavelength conversion component 1311 and the body of the linear lamp 1301. In the light bulb 1400 of FIGS. 11A and 11B, an interior volume 1415 is defined by the first wavelength conversion component 211′ and the body of the light bulb 1413 and another interior volume 1417 is defined by the second wavelength conversion component 213′ and the body of the light bulb 1413. Such an interior volume provides a physical separation (air gap) of the wavelength conversion component from the light emitters that improves the thermal characteristics of the light emitting device. Due to the isotropic nature of photoluminescence light generation, approximately half of the light generated by the phosphor material can be emitted in a direction towards the light emitters and can end up in the light mixing chamber. It is believed that on average as little as 1 in a 10,000 interactions of a photon with a phosphor material particle results in absorption and generation of photoluminescence light. The majority, about 99.99%, of interactions of photons with a phosphor particle result in scattering of the photon. Due to the isotropic nature of the scattering process on average half the scattered photons will be in a direction back towards the light emitters. As a result up to half of the light generated by the light emitters that is not absorbed by the phosphor material can also end up back in the light mixing chamber. To maximize light emission from the device and to improve the overall efficiency of the light emitting device the interior volume of the mixing chamber includes light reflective surfaces to redirect—light in—the interior volume towards the wavelength conversion component and out of the device. The light mixing chamber may also operate to mix light within the chamber. The light mixing chamber may also operate to mix light within the chamber. The light mixing chamber can be defined by the wavelength conversion component in conjunction with another component of the device such as a device body or housing (e.g., dome-shaped wavelength conversion component encloses light emitters located on a base of device body to define light mixing chamber, or planar wavelength conversion component placed on a chamber shaped component to enclose light emitters located on a base of device body and surrounded by the chamber shaped component to define light mixing chamber). For example, the downlight 1000 of FIGS. 8A, 8B, 8C includes an MCPCB 1009, on which the light emitters 207, 208 are mounted, comprising light reflective material and a light reflective chamber wall mask 1015 to facilitate the redirection of light reflected back into the interior volume towards the wavelength conversion component 209. The linear lamp 1300 of FIGS. 13A and 13B includes an MCPCB 1305, on which the light emitters 1303 are mounted, comprising light reflective material to facilitate the redirection of light reflected back into the interior volume towards the wavelength conversion component 1311. The light bulb 1400 of FIGS. 11A and 11B also includes an MCPCB 1405, on which the light emitters 207, 208 are mounted, to facilitate the redirection of light reflected back into the interior volume towards the wavelength conversion components 211′, 213′.

The above applications of light emitting devices describe only a few embodiments with which the claimed invention may be applied. It is important to note that the claimed invention may be applied to other types of light emitting device applications, including but not limited to, wall lamps, pendant lamps, chandeliers, recessed lights, track lights, accent lights, stage lighting, movie lighting, street lights, flood lights, beacon lights, security lights, traffic lights, headlamps, taillights, signs, etc.

Therefore, what has been described is a tunable solid-state light emitting device, which solves the problem of the undesirable dimming characteristics for prior art solid-state lighting devices. In some embodiments, the invention provides for a dimmer switch configured to generate a range of output powers for the light emitting device, a control circuit configured to translate an output power generated by the dimmer switch into an on/off arrangement of the plurality of light sources, and a wavelength conversion component comprising two or more regions with different photo-luminescent materials located remotely to the plurality of solid-state light sources and operable to convert at least a portion of the light generated by the plurality of solid-state light sources to light of a different wavelength, wherein the emission product of the device comprises combined light generated by the plurality of light sources and the two or more regions of the wavelength conversion component. This arrangement allows the lighting device to generate light that ranges from a bright bluish white to a warm yellowish white, and is capable of providing a color variation that more closely resembles that of the dimmable incandescent light bulb.

In the foregoing specification, the invention has been described with reference to specific embodiments thereof. It will, however, be evident that various modifications and changes may be made thereto without departing from the broader spirit and scope of the invention. For example, the above described wavelength conversion components are described with reference to two regions. However, the number of regions in the wavelength conversion component may be changed without affecting the scope or operation of the invention. The specification and drawings are, accordingly, to be regarded in an illustrative rather than restrictive sense.

What is claimed is:

1. A tunable light emitting device, comprising:
a plurality of solid-state light sources;
a control circuit to control distribution of power to the plurality of light sources; and
a wavelength conversion component comprising two or more regions, wherein the two or more regions correspond to different light emission colors, and different ones of the plurality of solid-state light sources correspond to different regions within the wavelength conversion component.
